(19) United States
(12) Patent Application Publication
(10) Pub. No.: US 2026/0117009 A1
(43) Pub. Date: Apr. 30, 2026

(54) UV CURABLE PROTECTIVE MATERIAL COMPOSITION WITH EXCELLENT FLAME RETARDANCY AND LED DISPLAY USING THE SAME

(71) Applicant: O-Flex Co., Ltd., Daejeon (KR)

(72) Inventors: Se Ra KIM, Daejeon (KR); Hyun Jee YOO, Daejeon (KR); Moon Cheol SHIN, Daejeon (KR); Hyeon A KIM, Daejeon (KR)

(21) Appl. No.: 18/984,317

(22) Filed: Dec. 17, 2024

(30) Foreign Application Priority Data
Oct. 29, 2024 (KR) 10-2024-0149381

(51) Int. Cl. C08F 220/18; C08K 5/5313; C08K 5/5399; H10H 29/854

(52) U.S. Cl. CPC C08F 220/1811; C08K 5/5313; C08K 5/5399; H10H 29/854

(57) ABSTRACT

Provided is an ultraviolet (UV)-curable protective material with excellent flame retardancy and a light-emitting diode (LED) display using the same, and more particularly, to a UV-curable protective material composition including an oligomer having at least one skeleton selected from polyisobutylene and hydrogenated polybutadiene and having a bifunctional acrylic group; an acrylic monomer; a photoinitiator; and a solid flame retardant including phosphorus, wherein the solid flame retardant has a D90 particle size of 2 to 20 μm, and the phosphorus is included in an amount of 10% by weight or more based on the total weight of the solid flame retardant. The UV-curable protective material composition exhibits excellent flame retardancy, optical properties, and durability and is suitable for application to LED displays and the like.

### CROSS-REFERENCE TO RELATED APPLICATION

This application claims priority to and the benefit of Korean Patent Application No. 10-2024-0149381, filed on Oct. 29, 2024, the disclosure of which is incorporated herein by reference in its entirety.

### STATEMENT REGARDING SPONSORED RESEARCH OR DEVELOPMENT

The research and development of the present disclosure were conducted with the support of the Startup Growth Technology Development Project of Korea Technology & Information Promotion Agency for SMEs of the Ministry of SMEs and Startups of the Republic of Korea, the research project having the title “Development of Eco-Friendly Molding Materials and Processes for Micro LED Modules that Reduce Production Energy by 90% and Reduce Fire Hazards”.

### BACKGROUND

### 1. Field of the Disclosure

The present disclosure relates to an ultraviolet (UV)-curable protective material with excellent flame retardancy and a light-emitting diode (LED) display using the same, and more particularly, to a UV-curable protective material composition including a solid flame retardant including phosphorus, wherein the solid flame retardant has a D90 particle size of 2 to 20 μm and the phosphorus is included in an amount of 10% by weight or more based on the total weight of the solid flame retardant, thereby exhibiting excellent flame retardancy, optical properties, and durability, and being suitable for application to LED displays and the like.

### 2. Discussion of Related Art

Since LEDs are sensitive to heat and moisture, when used without proper protection, they may deteriorate over time and their lifetime may be shortened. Furthermore, when LEDs are frequently exposed to the external environment, such as outdoor billboards or portable devices, high durability of displays is required. In particular, since LED displays use flammable materials, there is a concern that damage may increase significantly in the event of a fire, so protective materials with flame retardant performance need to be applied.

Various technologies have been attempting to provide flame retardant performance to the protective layer of LED displays to date, but in the case of halogen-based flame retardants with excellent flame retardancy, the amount used is regulated due to environmental issues, so there is a problem that it is impossible to apply halogen-based flame retardants in a sufficient amount to provide flame retardancy. In the case of non-halogen-based flame retardants, an excessive amount of flame retardant is required to secure sufficient flame retardant properties. However, when a solid flame retardant is used in an excessive amount, there is a concern that optical properties may deteriorate, and when a liquid flame retardant is used, adhesion and durability are weak due to fluidity, making it unsuitable as a protective material.

Accordingly, the present inventors have continued research on the development of a protective material capable of solving the above-described problems, and as a result, have confirmed that when a solid flame retardant having an appropriate D90 particle size and an appropriate phosphorus content is used, not only is the flame retardancy excellent, but also the optical properties and durability are excellent, making it suitable for application to LED displays, and the like, and have thus completed the present disclosure.

### SUMMARY OF THE DISCLOSURE

An object of the present disclosure is to provide a UV-curable protective material composition with excellent flame retardancy and an LED display using the same.

The technical problems of the present disclosure are not limited to the above-mentioned technical problems, and other technical problems that are not mentioned will be clearly understood by those skilled in the art from the descriptions below.

According to an embodiment of the present disclosure, provided is a UV-curable protective material composition, including: an oligomer having at least one skeleton selected from polyisobutylene and hydrogenated polybutadiene and having a bifunctional acrylic group; an acrylic monomer; a photoinitiator; and a solid flame retardant including phosphorus, wherein the solid flame retardant has a D90 particle size of 2 to 20 μm, and the phosphorus is included in an amount of 10% by weight or more based on the total weight of the solid flame retardant.

In addition, the UV-curable protective material composition may have a viscosity of 10 to 3000 cps before UV curing.

In addition, the UV-curable protective material composition may have a light transmittance of 75% or more at a thickness of 50 μm after UV curing.

In addition, the UV-curable protective material composition may have a tack force of 20 gf or less after UV curing.

In addition, the solid flame retardant may be a non-halogen solid flame retardant.

In addition, the solid flame retardant may include an organic flame retardant and an inorganic flame retardant.

In addition, the UV-curable protective material composition may have a Young's modulus of 100 to 7000 MPa at 25° C.

In addition, the UV-curable protective material composition may further include at least one of a pigment, a dye, an antioxidant, a heat stabilizer, a UV stabilizer, a UV absorber, and an antistatic agent.

According to another embodiment of the present disclosure, provided is a circuit board or display panel including the UV-curable protective material composition.

The UV-curable protective material composition of the present disclosure has excellent flame retardancy and optical properties, and may be suitable for protecting PCB boards, LEDs, and LED displays. Specifically, the UV-curable protective material composition has excellent flame retardancy despite not including a halogen-based flame retardant, and has excellent light transmittance despite including a solid flame retardant, and may be suitable for application to LED displays.

In addition, the UV-curable protective material composition has optimal Young's modulus and tack force for use as a flame retardant protective material and may have excellent resistance to physical damage, excellent exterior appearance, and excellent adhesion to a substrate.

Therefore, a PCB or LED display to which the UV-curable protective material composition of the present disclosure is applied may have excellent resistance to physical impact and flame retardancy, and may also have excellent display product quality.

### BRIEF DESCRIPTION OF THE DRAWINGS

The above and other objects, features and advantages of the present disclosure will become more apparent to those of ordinary skill in the art by describing exemplary embodiments thereof in detail with reference to the accompanying drawings, in which:

FIG. 1 shows a diagram illustrating a cross-sectional view of an LED display panel according to an embodiment of the present disclosure; and

FIG. 2 shows a diagram illustrating a cross-sectional view of an LED display panel according to another embodiment of the present disclosure.

### DETAILED DESCRIPTION OF EXEMPLARY EMBODIMENTS

Unless defined otherwise, all technical and scientific terms used herein have the same meaning as commonly understood by one of ordinary skill in the art to which the disclosure pertains. Generally, the nomenclature used herein is well known and commonly employed in the art. In addition, when describing embodiments of the present disclosure, when it is determined that a specific description of a related known feature or function hinders understanding of the embodiments of the present disclosure, the detailed description will be omitted. In addition, although embodiments of the present disclosure will be described below, the technical idea of the present disclosure is not limited or restricted thereto and may be modified and implemented in various ways by those skilled in the art.

Herein, when a part is said to be “connected,” “attached,” “adhered,” or “contacted” with another part, this includes not only cases where it is “directly connected,” but also cases where it is “electrically connected” with another element therebetween.

Herein, when it is said that a member is positioned “on,” “over,” “above,” “beneath” or “below” another member, this includes not only cases where a member is in contact with another member, but also cases where a third member is present between the two members.

Herein, when it is said that a member is positioned “directly on,” “directly over,” “directly above,” “directly beneath,” “directly below,” or “directly under” another member, it means that it is in contact with the other member, and there is no other member between the two members.

Herein, the spatially relative terms “below,” “beneath,” “lower,” “above,” “upper,” and the like may be used to easily describe the relationship between components as illustrated in the drawings.

Herein, when a part is said to include a component, this does not mean that other components are excluded, unless specifically stated otherwise, but rather that other components may further be included.

Herein, the term “and/or” includes a combination of a plurality of related items or any one of a plurality of related items.

According to an embodiment of the present disclosure, provided is a UV-curable protective material composition, including: an oligomer having at least one skeleton selected from polyisobutylene and hydrogenated polybutadiene and having a bifunctional acrylic group; an acrylic monomer; a photoinitiator; and a solid flame retardant including phosphorus, wherein the solid flame retardant has a D90 particle size of 2 to 20 μm, and the phosphorus is included in an amount of 10% by weight or more based on the total weight of the solid flame retardant.

In the present disclosure, when phosphorus is thermally decomposed by heat, phosphoric acid and/or metaphosphoric acid are generated, and these undergo esterification and/or dehydrogenation reactions to form a protective layer including carbon (charcoal), thereby blocking oxygen and exhibiting flame retardant properties. Therefore, the present inventors have made the UV-curable protective material composition include phosphorus in an amount sufficient to impart flame retardancy, thereby exhibiting excellent flame retardant properties. Specifically, in the present disclosure, phosphorus is included in an amount of 10% by weight or more based on the total weight of the solid flame retardant, and when the phosphorus content is less than 10% by weight based on the total weight of the solid flame retardant, the flame retardant properties may be decreased.

In the present disclosure, the “phosphorus content” corresponds to the total content of not only the content of pure phosphorus included in the solid flame retardant but also the content occupied by phosphorus in a compound containing phosphorus included in the solid flame retardant.

In addition, the present inventors have confirmed that when the D90 particle size of the solid flame retardant is 2 to 20 μm, excellent flame retardancy and optical properties are simultaneously satisfied. Specifically, a flame retardant forms a protective layer by generating phosphoric acid and/or metaphosphoric acid through thermal decomposition and blocks oxygen to prevent combustion, and it has been confirmed that when the D90 particle size is less than 2 μm, an organic matrix that is prone to combustion protective layer is difficult to be formed, resulting in insufficient flame retardancy. It has been confirmed that when the D90 particle size of the solid flame retardant exceeds 20 μm, the gaps between the particles of the flame retardant are large, which reduces the performance of retarding ignition of the organic matrix, resulting in poor flame retardancy properties. In addition, when the D90 particle size exceeds 20 μm, the optical performance was reduced when used as a material for protecting the top of an LED.

The term, “D90 particle size” as used herein refers to a particle size corresponding to 90% of the cumulative percentage of the number of particles when the total amount of powder is expressed as a percentage by accumulating particles with different size intervals from the smallest size. For example, when the D90 particle size is 25 μm, the number of particles with a particle size of 25 μm or less corresponds to 90% of the total number of particles, and the number of particles with a particle size exceeding 25 μm corresponds to 10% of the total number of particles. D50 (average particle size), which means a general particle size, refers to a particle size corresponding to a cumulative percentage distribution and is different from the D90 particle size. The D90 particle size may not be estimated through D50, and even when the D50 size is similar depending on the particle size distribution, the D90 size may be different.

The term “oligomer” as used herein may refer to a polymer in which monomers are polymerized with a degree of polymerization of 5 to 10,000. Therefore, the term “oligomer having a bifunctional acrylic group” as used herein may refer to a polymer having two functional acrylic groups in which the monomers are polymerized with a degree of polymerization of 5 to 10,000.

The UV-curable protective material composition of the present disclosure has an oligomer having at least one skeleton selected from polyisobutylene and hydrogenated polybutadiene and having a bifunctional acrylic group, thereby significantly reducing moisture and gas permeability and providing a protective layer having excellent protective performance and excellent durability for an LED mounted on at least one of a printed circuit board (PCB) and the interior of a display. When the oligomer has one acrylic functional group, the UV-curing speed may significantly decrease or the durability and reliability may deteriorate due to an uncured material, and when the oligomer has three or more acrylic functional groups, the crosslinking density increases, causing cracks to be generated in the cured protective material composition, and separation occurs between the LED in contact with the protective layer and the solder resist layer, thereby significantly reducing the durability and reliability.

In one embodiment, the solid flame retardant of the present disclosure may be a non-halogen solid flame retardant. By including the non-halogen solid flame retardant, the hazard of the protective material composition of the present disclosure to the environment or human body can be significantly reduced.

In one embodiment, the solid flame retardant of the present disclosure may include an organic flame retardant and an inorganic flame retardant. By including both the organic flame retardant and the inorganic flame retardant, more excellent flame retardant properties may be imparted to the UV-curable protective material composition. For example, the solid flame retardant of the present disclosure may include a non-halogen organic flame retardant and a non-halogen inorganic flame retardant. The UV-curable protective material composition of the present disclosure can exhibit excellent flame retardant properties even when it includes the non-halogen organic flame retardant and the non-halogen inorganic flame retardant.

The term “organic flame retardant” as used herein refers to a flame retardant including the carbon (C) element, and the term “inorganic flame retardant” refers to a flame retardant not including the carbon (C) element.

In one embodiment, the solid flame retardant of the present disclosure may include aromatic phosphoric acid esters, mono-substituted phosphonic acid diesters, di-substituted phosphinic acid esters, metal salts of di-substituted phosphinic acids, nitrogen-containing phosphorus compounds, cyclic phosphorus compounds, alkylphosphinate salts, aluminum phosphites, and phosphine oxides, but is not limited thereto.

As an example of the aromatic phosphoric acid esters, at least one of 1,3-phenylenebis(di-2,6-xylenyl phosphate), bisphenol α-bis(diphenyl phosphate), and 1,3-phenylenebis(diphenyl phosphate) may be included.

As an example of the mono-substituted phosphonic acid diesters, at least one of phenylphosphonic acid divinyl, diallyl phenylphosphonate, and phenylphosphonic acid bis(1-butenyl) may be included.

As an example of the di-substituted phosphinic acid esters, at least one of phenyl diphenylphosphinate and methyl diphenylphosphinate may be included.

As an example of the nitrogen-containing phosphorus compounds, at least one of phosphazene compounds such as hexaphenoxycyclotriphosphazene, bis(2-allylphenoxy)phosphazene, and dicresyl phosphazene; melamine-based compounds such as melamine phosphate, melamine pyrophosphate, melamine polyphosphate, and melam polyphosphate; ammonium polyphosphate, ammonium phosphate, monoammonium phosphate, diammonium phosphate, triammonium phosphate, and ammonium polyphosphate.

As an example of the cyclic phosphorus compounds, at least one of 9,10-dihydro-9-oxa-10-phosphaphenanthrene-10-oxide and 10-(2,5-dihydroxyphenyl)-9,10-dihydro-9-oxa-10-phosphaphenanthrene-10-oxide may be included.

As an example of the alkyl phosphinate salt, at least one of aluminum diethyl phosphinate, aluminum methylethyl phosphinate, titanyl bis(diethyl phosphinate), titanyl tetrakis(diethyl phosphinate), titanyl bis(methylethyl phosphinate), titanyl tetrakis(methylethyl phosphinate), zinc bis(diethyl phosphinate), and zinc bis(methylethyl phosphinate) may be included.

In one embodiment, the oligomer having at least one skeleton selected from polyisobutylene and hydrogenated polybutadiene has a weight average molecular weight (Mw) of 3,000 to 100,000, specifically, a weight average molecular weight of 5,000 to 95,000. In this case, when the weight average molecular weight is 3,000 or less, the durability and reliability after UV curing may be poor due to high crosslinking density and brittleness, and when it is 100,000 or more, the UV curing may not be performed smoothly, resulting in a problem of poor durability and reliability due to unreacted substances.

In one embodiment, the content of the oligomer having at least one skeleton selected from polyisobutylene and hydrogenated polybutadiene may be included in an amount of 10 to 50 parts by weight. When the content of the oligomer is less than 10 parts by weight, problems such as LED damage and corrosion of the circuit surface exposed to the PCB may occur due to a decrease in the external moisture blocking properties, and when it exceeds 50 parts by weight, bubbles may be easily generated and may not be easily removed during application due to high viscosity.

In one embodiment, the acrylic monomer may include a functional group capable of chemically bonding to a solder resist formed on the top of the PCB.

In one embodiment, as the acrylic monomer, at least one selected from the group consisting of methyl methacrylate, ethyl methacrylate, n-propyl methacrylate, isopropyl methacrylate, n-butyl methacrylate, t-butyl methacrylate, sec-butyl methacrylate, pentyl methacrylate, 2-ethylhexyl methacrylate, n-hexyl acrylate, n-octyl methacrylate, isooctyl methacrylate, isononyl methacrylate, isobornyl methacrylate, glycidyl methacrylate, hydroxyethyl methacrylate, lauryl methacrylate, tetradecyl methacrylate, benzyl methacrylate, cyclohexyl methacrylate, tetrahydrofurfuryl methacrylate, or morpholinyl methacrylate, a methacrylate having an alkoxy group, or acrylic acid may be used. Specifically, the acrylic monomer may have one or more of epoxy, isocyanate, hydroxy, silane, amide, and amine.

In one embodiment, as the acrylic monomer epoxy methacrylate, 2-hydroxyethyl methacrylate, 3-hydroxypropyl methacrylate, 4-hydroxybutyl methacrylate, 3-(meth)acroyloxy propyl triethoxy silane, 3-methacroyloxy propyl trimethoxy silane, N,N-dimethyl acrylamide, N,N-diethyl acrylamide, or methacryloyloxyethyl isocyanate, and specifically, epoxy methacrylate may be used. In this case, the adhesion between the cured protective material composition of the present disclosure and the solder resist on the surface of the PCB is improved, thereby improving durability and reliability and preventing bubble generation and peeling.

In one embodiment, the acrylic monomer may be included in an amount of 50 to 90 parts by weight. When the content of the acrylic monomer is less than 50 parts by weight, there is a problem in that bubbles are generated and the bubbles are not easily removed due to high viscosity when the UV-curable protective material composition is applied. When it exceeds 90 parts by weight, there is a problem in that the toughness of the cured protective material composition is weak, and cracks are easily generated by physical impact.

As the photoinitiator, one that is activated by UV may be used, and when the photoinitiator is irradiated with UV, it generates radicals that initiate polymerization. In the present disclosure, as the photoinitiator, a general photoinitiator component that may be used in the art may be used without limitation, and various photoinitiators such as ketones of benzophenone and acetophenone, peroxides or phosphine oxides, benzoin, benzoin ether, benzyl, and benzyl ketal may be selected and used as the photoinitiator component. As a specific example, at least one of 1-hydroxy cyclohexyl phenyl ketone, 1-hydroxy-2-methyl-1-phenylpropane-1-ketone, 2-chlorothioxantone, 2-isopropylthioxantone, 2,2-dimethoxy-2-phenylacetophenone, 2,4,6-trimethylbenzoyl-diphenyl phosphine oxide, ethyl(2,4,6-trimethylbenzoyl)-phenylphosphinate, bis(2,4,6-trimethylbenzoyl)-phenylphosphineoxide, and benzophenone may be used.

In one embodiment, the photoinitiator may be included in an amount of 0.05 to 5 parts by weight. When the content of the photoinitiator is less than 0.05 parts by weight, UV curing is likely to not occur sufficiently, and when it exceeds 5 parts by weight, unreacted photoinitiator may remain in the cured protective material composition, which may cause a yellowing problem.

In one embodiment, the solid flame retardant may be included in an amount of 20 to 100 parts by weight based on 100 parts by weight of an oligomer having at least one skeleton selected from polyisobutylene and hydrogenated polybutadiene and having a bifunctional acrylic group; and an acrylic monomer.

In one embodiment, the UV-curable protective material composition of the present disclosure may further include one or more of a pigment, a dye, an antioxidant, a heat stabilizer, a UV stabilizer, a UV absorber, a flame retardant, and an antistatic agent, and any known material may be used as the components without limitation. The mixing amount of the above-described components is not particularly limited, and may be easily selected by one of ordinary skill in the art within a range that does not impair the purpose and effect of the present disclosure.

In one embodiment, the UV-curable protective material composition of the present disclosure may have a viscosity of 10 to 3,000 cps before UV curing, and specifically, may have a viscosity in a range of 100 to 2,500 cps. By having a viscosity in the above-described range, the possibility of bubble generation around an LED when applying the protective material composition can be eliminated, and the resulting deterioration in image quality and performance of a display can be prevented. On the other hand, when the viscosity of the UV-curable protective material composition exceeds 3,000 cps, bubbles may be easily generated around an LED and the generated bubbles may not be easily removed when applying the UV-curable protective material composition onto a PCB. Therefore, this may deteriorate the optical properties of the display device and may cause poor durability and reliability and/or exterior appearance.

In one embodiment, the UV-curable protective material composition of the present disclosure may have a Young's modulus of 100 to 7,000 MPa at 25° C., specifically, 120 MPa to 6,500 MPa. When the above-described numerical range is satisfied, the UV-curable protective material composition may have performance capable of sufficiently protecting a PCB and components laminated on the PCB, including an LED, from physical impact. On the other hand, when the Young's modulus is less than 100 MPa, the protective material composition has a weak resistance to physical damage, and when it exceeds 7,000 MPa, there is a limitation that cracks are generated in the protective material composition when a physical impact is applied, making it impossible to sufficiently protect the LED under durability and reliability conditions.

In one embodiment, the UV-curable protective material composition of the present disclosure may have a tack force of 20 gf or less after UV curing. In one specific embodiment, the UV-curable protective material composition may be applied to one surface of a PCB and UV-cured to form a protective layer constituting the outermost surface of an LED display. At this time, since the tack force after UV curing is less than 20 gf and the protective layer has tackiness of a predetermined value or lower, the surface of the protective layer exposed to the outside may remain uncontaminated, so there is no concern about damage to the image quality of the LED display.

In one embodiment, the UV-curable protective material composition of the present disclosure may have a light transmittance of 75% or more at a thickness of 50 μm after UV curing. By having the above-described light transmittance, the UV-curable protective material composition of the present disclosure may be suitable as a composition for protecting a PCB and/or an LED display by simultaneously having excellent flame retardant properties and optical properties.

According to another embodiment of the present disclosure, a PCB or display panel including the UV-curable protective material composition of the present disclosure is provided.

A PCB refers to a substrate capable of mounting electronic devices, and thus capable of mounting various types of electronic devices and connecting the electronic devices. Examples of the devices may include passive devices including resistors, capacitors, inductors, transformers, and diodes; active devices including transistors and integrated devices; power devices including voltage regulators and relays; signal devices including oscillators and sensors; optoelectronic devices including LEDs, organic light-emitting diodes (OLEDs), photodiodes, and liquid crystal displays (LCDs); memory devices including flash memories and dynamic random-access memories (DRAMs); and the like, but are not limited thereto.

The PCB may include the UV-curable protective material composition of the present disclosure and form a protective layer, thereby protecting various electronic devices mounted on the substrate.

A display panel refers to a component that generates an image of a display. The display panel may include the UV-curable protective material composition of the present disclosure; and at least one display device of LED, OLED, and LCD; and may implement a display with excellent image quality due to the excellent optical properties of the protective material composition.

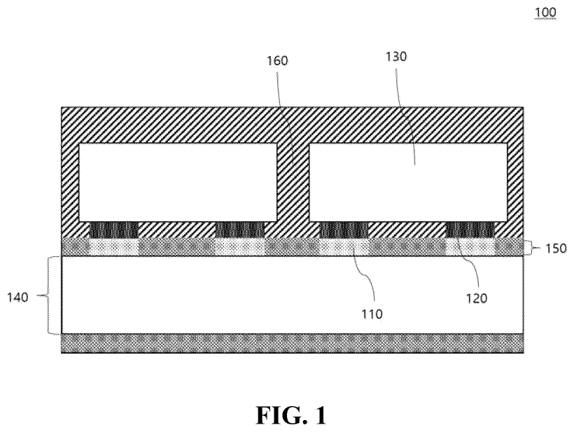

FIG. 1 illustrates an example of an LED display panel to which the UV-curable protective material composition of the present disclosure is applied and shows a cross-sectional view of an LED display panel including a protective layer formed with the UV-curable protective material composition of the present disclosure.

One embodiment of the present disclosure provides an LED display 100 including: a PCB 140; an electrode layer 110 positioned at least on a part of the top front surface of the PCB 140; a solder 120 formed on at least a part of the electrode layer 110; an LED 130 positioned on the solder 120 and connected to the electrode layer 110; and a solder resist 150 positioned on the top front surface of the PCB 140 except for the region of the electrode layer 110; and a protective layer 160 applied to the front surface of the PCB 140 on which the electrode layer 110 region and the solder resist 150 are laminated.

In one embodiment of the present disclosure, the thickness of the protective layer 160 measured from the top layer of the PCB 140 may be greater than or equal to the sum of the thickness of the solder and the thickness of the LED.

One or more other layers may be laminated on the protective layer 160, or the protective layer 160 may form the outermost surface of the LED display.

The protective layer 160 is formed by curing the UV-curable protective material composition of the present disclosure with UV light and has excellent adhesion to the surface of the PCB 140 and strong resistance to external impact or scratches, so that it may perform a physical protection function of the LED 130. In addition, the protective layer 160 optimizes optical properties to prevent deterioration of the light-emitting properties of the LED 130. Through this design, high image quality and durability can be maintained at the same time in an LED display device. In addition, the protective layer 160 has low moisture transmittance, excellent weather resistance, and durability properties, thereby protecting the LED, while minimizing damage to the image quality of the LED display caused by the protective layer 160.

In another embodiment of the present disclosure, the LED display according to the implementation of the present disclosure may include a light control film on top of the protective layer. The light control film may be used without limitation as long as it is a film having the functions of diffusing, refracting, reflecting, dispersing, and absorbing light, and may be optionally used for the purpose of improving the visibility and color viewing angle of an LED display.

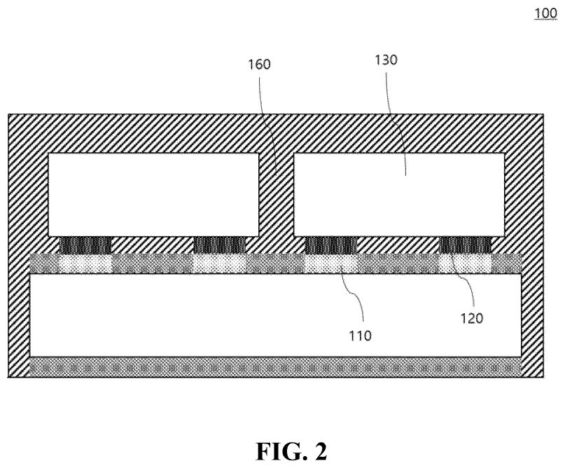

FIG. 2 shows a cross-sectional view of an LED display panel including the protective layer as another embodiment of the present disclosure.

As shown in FIG. 2, the protective layer 160 may have a structure in which it is applied to the side surface of the PCB 140, thereby protecting the LED 130 from external impact and protecting the LED 130 and the circuit surface from external heat and moisture.

Hereinafter, examples and experimental examples are presented to further explain the present disclosure, but the present disclosure is not limited thereto.

### Manufacturing Examples

### Manufacturing of Example 1

35 parts by weight of a bifunctional acrylate oligomer having a weight average molecular weight of 27,000 and a polyisobutylene structure, 45 parts by weight of isobornyl acrylate, 12 parts by weight of isooctyl acrylate, and 8 parts by weight of glycidyl methacrylate were uniformly blended. Based on 100 parts by weight of the blended solution, 68 parts by weight of aluminum diethylphosphinate (non-halogen solid organic flame retardant) having a phosphorus content of 24% by weight based on the total weight of the solid organic flame retardant and a D90 particle size of 10 μm was added, and 1.0 part by weight of 2,2-dimethoxy-2-phenylacetophenone (IRGACURE 651, Ciba Specialty Chemicals) as a photoinitiator was further added, mixed, and defoamed to prepare an UV-curable protective material composition.

### Manufacturing of Example 2

16 parts by weight of a bifunctional acrylate oligomer having a weight average molecular weight of 45,000 and including a hydrogenated polybutadiene structure, 39 parts by weight of isobornyl acrylate, 25 parts by weight of lauryl methacrylate, 5 parts by weight of hydroxy butyl acrylate, and 15 parts by weight of glycidyl methacrylate were uniformly blended. Based on 100 parts by weight of the blended solution, 20 parts by weight of hexaphenoxycyclotriphosphazene (non-halogen solid organic flame retardant) having a phosphorus content of 13% by weight based on the total weight of the solid organic flame retardant and a D90 particle size of 5 μm, 10 parts by weight of ammonium polyphosphate (non-halogen solid inorganic flame retardant) having a phosphorus content of 30% by weight based on the total weight of the solid inorganic flame retardant and a D90 particle size of 18 μm were added, and 1.0 part by weight of 2,2-dimethoxy-2 phenylacetophenone (IRGACURE 651, Ciba Specialty Chemicals Inc.) as a photoinitiator was further added, mixed, and defoamed to prepare a UV-curable protective material composition.

### Manufacturing of Comparative Example 1

35 parts by weight of a bifunctional acrylate oligomer having a weight average molecular weight of 27,000 and a polyisobutylene structure, 45 parts by weight of isobornyl acrylate, 12 parts by weight of isooctyl acrylate, and 8 parts by weight of glycidyl methacrylate were uniformly blended. Based on 100 parts by weight of the blended solution, 54 parts by weight of triphenyl phosphate (non-halogen solid organic flame retardant) having a phosphorus content of 9% by weight based on the total weight of the solid organic flame retardant and a D90 particle size of 3 μm was added, and 1.0 part by weight of 2,2-dimethoxy-2-phenylacetophenone (IRGACURE 651, Ciba Specialty Chemicals Inc.) as a photoinitiator was further added, mixed, and defoamed to prepare a UV-curable protective material composition.

### Manufacturing of Comparative Example 2

35 parts by weight of a bifunctional acrylate oligomer having a weight average molecular weight of 27,000 and a polyisobutylene structure, 45 parts by weight of isobornyl acrylate, 12 parts by weight of isooctyl acrylate, and 8 parts by weight of glycidyl methacrylate were uniformly blended. Based on 100 parts by weight of the blended solution, 68 parts by weight of diethyl phosphate (non-halogen solid organic flame retardant) having a phosphorus content of 24% by weight based on the total weight of the solid organic flame retardant and a D90 particle size of 31 μm was added, and 1.0 part by weight of 2,2-dimethoxy-2-phenylacetophenone (IRGACURE 651, Ciba Specialty Chemicals Inc.) as a photoinitiator was further added, mixed, and defoamed to prepare a UV-curable protective material composition.

### Manufacturing of Comparative Example 3

35 parts by weight of a bifunctional acrylate oligomer having a weight average molecular weight of 27,000 and a polyisobutylene structure, 45 parts by weight of isobornyl acrylate, 12 parts by weight of isooctyl acrylate, and 8 parts by weight of glycidyl methacrylate were uniformly blended. Based on 100 parts by weight of the blended solution, 55 parts by weight of cyclic phosphate ester (non-halogen liquid organic flame retardant) having a phosphorus content of 20% by weight based on the total weight of the liquid organic flame retardant was added, and 1.0 part by weight of 2,2-dimethoxy-2-phenylacetophenone (IRGACURE 651, Ciba Specialty Chemicals Inc.) as a photoinitiator was further added, mixed, and defoamed to prepare a UV-curable protective material composition.

### Manufacturing of Comparative Example 4

35 parts by weight of a tetrafunctional acrylate oligomer having a weight average molecular weight of 19,000 and a hydrogenated polybutadiene structure, 24 parts by weight of lauryl methacrylate, 35 parts by weight of isobornyl acrylate, and 6 parts by weight of glycidyl methacrylate were uniformly blended. Based on 100 parts by weight of the blended solution, 45 parts by weight of aluminum diethylphosphinate (non-halogen solid organic flame retardant) having a phosphorus content of 24% by weight based on the total weight of the solid organic flame retardant and a D90 particle size of 10 μm was added, and 1.0 part by weight of 2,2-dimethoxy-2-phenylacetophenone (IRGACURE 651, Ciba Specialty Chemicals Inc.) as a photoinitiator was further added, mixed, and defoamed to obtain a UV-curable protective material composition.

### Experimental Examples

### (1) Evaluation of Flame Retardancy

The compositions prepared in the above examples and comparative examples were applied to the entire surface of a PCB panel mounted with a 250-μm high LED so that the height became 500 μm, and then a polyester release film was laminated on the applied protective layer to prevent contact with oxygen. Thereafter, UV was irradiated on the polyester release film surface using a 365-nm LED UV lamp so that the light amount was 3000 mJ/cm² in order to cure the compositions, and the polyester release film was removed to complete the LED panel.

The panel manufactured above was cut to a width of 13 mm and a length of 125 mm, and at least five samples were prepared, and the flame retardancy was evaluated using the UL94 V test method as described below.
1) The specimen was brought into contact with a 20 mm long flame for 10 seconds, and then the combustion time t1 of the specimen was measured, and the combustion pattern was recorded.
2) After the combustion is completed following the first contact, the specimen was brought into contact again for another 10 seconds, the combustion time t2 of the specimen and the time t3 when the sparks are formed were measured, and the combustion pattern was recorded.
3) The combustion time and combustion pattern (whether the cotton surface was ignited by dripping, whether the combustion reached the clamp, etc.) of t1, t2, and t3 were determined, and the grade was calculated as shown in Table 1 below. When the grade is not included in any of the V-0, V-1, or V-2 grades below (non-graded), it is considered to have no flame retardancy.

TABLE 1

| | V-0 | V-1 | V-2 |
|---|---|---|---|
| Individual afterflame time (t1 or t2) | ≤10 sec | ≤30 sec | ≤30 sec |
| Total afterflame time for any condition | ≤50 sec | ≤250 sec | ≤250 sec |
| set (t1 + t2 for the 5 specimens) | | | |
| Afterflame plus afterglow time for each | ≤30 sec | ≤60 sec | ≤60 sec |
| individual specimen after the second | | | |
| flame application (t2 + t3) | | | |
| Burning up to the holding clamp | No | No | No |
| (marked as 125 mm) | | | |
| Cotton ignition by dripping | No | No | Yes |

### (2) Measurement of Light Transmittance

The compositions prepared in the examples and comparative examples were applied to the polyester release film using a bar coater to a thickness of 50 μm to form a protective material layer, and at this time, a polyester release film was additionally laminated on the formed protective layer to prevent contact between the protective material layer and oxygen. Thereafter, UV was irradiated on one side surface using a 365-nm LED UV lamp to a light amount of 3000 mJ/cm² in order to cure the compositions, and the release films on both sides were removed to manufacture a single sample of the UV-cured protective material layer.

Base line calibration was performed on the protective material prepared above in a state where no sample was present in the measurement section, and then the light transmittance was measured using NDH-7000 (Nippon Denshoku CO. LTD.) according to the JIS K 7105 standard.

### (3) Measurement of Viscosity

The viscosity of the compositions prepared in the examples and comparative examples was measured at room temperature after adjusting the revolution per minute (RPM) to apply 20 to 40% of torque with a No. 64 spindle using a Brookfield viscometer.

### (4) Measurement of Young's Modulus

The compositions prepared in the examples and comparative examples were applied to a polyester release film using a bar coater to a thickness of 500 μm to form a protective material layer, and at this time, a polyester release film was additionally laminated on the formed protective layer to prevent contact between the protective material layer and oxygen. Thereafter, UV was irradiated on one side surface using a 365-nm LED UV lamp to a light amount of 3000 mJ/cm² in order to cure the compositions, and the release films on both sides were removed to manufacture a single sample of the UV-cured protective material layer.

The UV-cured auxiliary material layer manufactured above was cut to a width of 10 mm and a length of 100 mm to prepare a measurement specimen. After maintaining the measurement environment at 25° C., the specimen was fixed between two jigs at a distance of 50 mm using universal testing machine (UTM) equipment, and then tension was applied at a speed of 100 mm/min until the sample was fractured to obtain a stress-strain curve. At this time, the slope of the strain section from 0.1% to 1% was calculated to obtain the Young's modulus value.

### (5) Measurement of Tack Force

The compositions prepared in the above examples and comparative examples were applied to the entire surface of a PCB panel mounted with a 250-μm high LED so that the height became 500 μm, and then a polyester release film was laminated on the applied protective layer to prevent contact with oxygen. Thereafter, UV was irradiated on the polyester release film surface using a 365-nm LED UV lamp so that the light amount was 3000 mJ/cm² in order to cure the compositions, and the polyester release film was removed to complete the LED panel. Using a texture analyzer, a 1-inch SUS ball was pressed at a speed of 0.1 mm/s to 800 gf on the outermost protective layer surface, held for 1 second, and then the maximum force required to return at a speed of 1 mm/s was recorded as the tack force.

### (6) Adhesion Evaluation

The compositions prepared in the above examples and comparative examples were applied to the entire surface of a PCB panel mounted with a 250-μm high LED so that the height became 500 μm, and then a polyester release film was laminated on the applied protective layer to prevent contact with oxygen. Thereafter, UV was irradiated on the polyester release film surface using a 365-nm LED UV lamp so that the light amount was 3000 mJ/cm² in order to cure the compositions, and the polyester release film was removed to complete the LED panel. The boundary surface of the PCB and the protective material was separated from the side surface using a blade, and the adhesion was evaluated using the evaluation criteria described below.
O: No lifting/peeling of PCB and protective material.
X: Lifting/peeling of PCB and protective material.

### (7) Exterior Appearance Observation

The compositions prepared in the above examples and comparative examples were applied to the entire surface of a PCB panel mounted with a 250-μm high LED so that the height became 500 μm, and then a polyester release film was laminated on the applied protective layer to prevent contact with oxygen. Thereafter, UV was irradiated on the polyester release film surface using a 365-nm LED UV lamp so that the light amount was 3000 mJ/cm² in order to cure the compositions, and the polyester release film was removed to complete the LED panel. The presence or absence of bubbles around the LED was observed using a microscope.
O: No bubbles generated around the LED
X: Bubbles generated around the LED

### (8) Durability and Reliability

The compositions prepared in the above examples and comparative examples were applied to the entire surface of a PCB panel mounted with a 250-μm high LED so that the height became 500 μm, and then a polyester release film was laminated on the applied protective layer to prevent contact with oxygen. Thereafter, UV was irradiated on the polyester release film surface using a 365-nm LED UV lamp so that the light amount was 3000 mJ/cm² in order to cure the compositions, and the polyester release film was removed to complete the LED panel. The manufactured LED panel was allowed to stand under high-temperature and high-humidity conditions of 85° C. and 85% relative humidity (RH) for 300 hours, and then the exterior appearance change and the presence of LED damage were observed.
O: No change in the exterior appearance such as bubbles or lifting, and full light emission during operation without LED damage
X: Change in the exterior appearance such as bubbles or lifting, and areas without LED light emission found during operation due to LED damage

The results of the experiments performed using the methods described in (1) to (8) above are shown in Table 2 below.

| | | | Comparative | Comparative | Comparative | Comparative |
|---|---|---|---|---|---|---|
| | Example | Example | Example | Example | Example | Example |
| | 1 | 2 | 1 | 2 | 3 | 4 |
| Flame | V-0 | V-0 | Non-graded | Non-graded | V-2 | V-0 |
| retardancy | | | | | | |
| Light | 89 | 77 | 83 | 90 | 67 | 87 |
| transmittance | | | | | | |
| Viscosity | 980 | 1580 | 2042 | 743 | 275 | 1257 |
| (cps) | | | | | | |
| Young's | 1051 | 2057 | 985 | 547 | 85 | 875 |
| modulus | | | | | | |
| (MPa) | | | | | | |
| Tack force | 2 | 1 | 2 | 8 | 45 | 5 |
| (gf) | | | | | | |
| Adhesion | ◯ | ◯ | ◯ | ◯ | X | ◯ |
| Exterior | ◯ | ◯ | ◯ | ◯ | ◯ | ◯ |
| appearance | | | | | | |
| Durability | ◯ | ◯ | ◯ | ◯ | X | X |
| and | | | | | | |
| reliability | | | | | | |

As shown in Table 2 above, it was confirmed that both Examples 1 and 2 exhibited excellent flame retardancy of V-0, having excellent optical properties with high light transmittance. In addition, since they had an appropriate viscosity of 10 to 3000 cps before UV curing, it was confirmed that they were suitable for application to PCBs, and when applied to LED displays, it was confirmed that no bubbles or the like were generated, and the Young's modulus was 100 to 7000 MPa, confirming that they had excellent resistance to physical impact. Therefore, it was confirmed that the UV-curable protective material composition of the present disclosure has excellent flame retardancy, optical properties, and resistance to physical impact, and thus is suitable for use as a composition for protecting PCBs or LED displays.

On the other hand, Comparative Example 1, of which phosphorus content was less than an appropriate amount, and Comparative Example 2, which had a D90 particle size exceeding 20 μm, were not given a flame retardancy grade, indicating that their flame retardant properties were poor, and Comparative Example 3, which was prepared by using a liquid flame retardant, exhibited poor flame retardant properties and light transmittance compared to the examples, had very high tack force and so was vulnerable to contamination, and had significantly low Young's modulus, indicating that their resistance to physical impact was significantly poor. It was confirmed that Comparative Example 4, which included a tetrafunctional acrylate oligomer including four functional groups, had poor durability and reliability under high-temperature and high-humidity conditions, indicating that it is not suitable for a protective material composition for LEDs, and the like.

Therefore, it was confirmed that, for the implementation of the present disclosure, it is an important to use a solid flame retardant including an appropriate amount of phosphorus and satisfying a D90 particle size condition.

As described above, specific parts of the content of the present disclosure have been described in detail. It will be obvious to those skilled in the art that such specific description is only a preferred embodiment and that the scope of the present disclosure is not limited thereby. Therefore, the substantial scope of the present disclosure is defined by the appended claims and their equivalents.

[Reference numerals]

| | |
|---|---|
| 100: LED display | 110: Electrode layer |
| 120: Solder | 130: LED |
| 140: PCB | 150: Solder resist |
| 160: Protective layer | |

What is claimed is:

1. A UV-curable protective material composition comprising:
an oligomer having at least one skeleton selected from polyisobutylene and hydrogenated polybutadiene and having a bifunctional acrylic group;
an acrylic monomer;
a photoinitiator; and
a solid flame retardant including phosphorus,
wherein the solid flame retardant has a D90 particle size of 2 to 20 μm, and the phosphorus is included in an amount of 10% by weight or more based on a total weight of the solid flame retardant.

2. The UV-curable protective material composition according to claim 1, wherein the UV-curable protective material composition has a viscosity of 10 to 3000 cps before UV curing.

3. The UV-curable protective material composition according to claim 1, wherein the UV-curable protective material composition has a light transmittance of 75% or more at a thickness of 50 μm after UV curing.

4. The UV-curable protective material composition according to claim 1, wherein the UV-curable protective material composition has a tack force of 20 gf or less after UV curing.

5. The UV-curable protective material composition according to claim 1, wherein the solid flame retardant is a non-halogen solid flame retardant.

6. The UV-curable protective material composition according to claim 1, wherein the solid flame retardant further includes an organic flame retardant and an inorganic flame retardant.

7. The UV-curable protective material composition according to claim 1, wherein the UV-curable protective material composition has a Young's modulus of 100 to 7000 MPa at 25° C.

8. The UV-curable protective material composition according to claim 1, wherein the UV-curable protective material composition further comprises at least one of a pigment, a dye, an antioxidant, a heat stabilizer, a UV stabilizer, a UV absorber, and an antistatic agent.

9. A circuit board comprising the UV-curable protective material composition according to claim 1.

10. A display panel comprising the UV-curable protective material composition according to claim 1.
